(19) United States
(12) Patent Application Publication
(10) Pub. No.: US 2026/0035600 A1
(43) Pub. Date: Feb. 5, 2026

(54) COLOR ABSORBING ADHESIVE COMPOSITIONS

(71) Applicant: 3M INNOVATIVE PROPERTIES COMPANY, St. Paul, MN (US)

(72) Inventors: Encai Hao, Woodbury, MN (US); Stephen M. Menke, Eagan, MN (US); Zhicheng Tian, Woodbury, MN (US)

(21) Appl. No.: 19/099,971

(22) PCT Filed: Aug. 22, 2023
(86) PCT No.: PCT/IB2023/058365

§ 371 Date: Jan. 30, 2025

Related U.S. Application Data
(60) Provisional application No. 63/401,782, filed on Aug. 29, 2022.

(51) Int. Cl. C09J 11/06; C09J 7/38; H10K 59/38

(52) U.S. Cl. CPC C09J 11/06; C09J 7/385; H10K 59/38; C09J 2203/326; C09J 2301/302; C09J 2301/408; C09J 2301/414

(57) ABSTRACT

Color absorbing adhesive compositions include an optically clear pressure sensitive adhesive and at least one light absorbing component dispersed within the pressure sensitive adhesive. The light absorbing component is a dye that has a peak absorption at 555-600 nanometers and has a Full Width at Half Maximum (FWHM) of no more than 70 nanometers. Articles have a layer of the color absorbing adhesive on an optical substrate.

### SUMMARY

Disclosed herein are color absorbing adhesive compositions and articles prepared from these color absorbing adhesive compositions. In some embodiments, the adhesive composition comprises an optically clear pressure sensitive adhesive, and at least one light absorbing component dispersed within the pressure sensitive adhesive. The at least one light absorbing component comprises a dye that has a peak absorption at 555-600 nanometers and has a Full Width at Half Maximum (FWHM) of no more than 70 nanometers.

Also disclosed are articles that contain the color absorbing adhesive compositions. In some embodiments, the articles comprise an optical substrate with a first major surface and a second major surface, and an adhesive layer disposed on at least a portion of the first major surface of the optical substrate, wherein the adhesive layer comprises the adhesive compositions described above.

### BRIEF DESCRIPTION OF THE DRAWINGS

The present application may be more completely understood in consideration of the accompanying drawings.

FIG. 1 is a graph showing the reduction in reflection of the CIE standard illuminant D65 spectrum weighted by the photopic sensitivity of the human eye.

FIG. 2 is a graph showing the tabulated reduction of an OLED white spectrum consisting of blue, green, and red emission bands.

### DETAILED DESCRIPTION

A wide range of optical articles are being developed for a wide range of uses. Among the optical articles are optical filters. Optical filters are employed in a wide variety of applications such as optical communication systems, sensors, imaging, scientific and industrial optical equipment, and display systems. Optical filters may include optical layers that manage the transmission of incident electromagnetic radiation, including light. Optical filters may reflect or absorb a portion of incident light and transmit another portion of incident light. Optical layers within an optical filter may differ in wavelength selectivity, optical transmittance, optical clarity, optical haze, and index of refraction. The optical layers may be films, including multi-layer films and adhesive layers.

Optically clear adhesives (optical grade PSAs, hereinafter referred to as “OCA”) are widely used in a wide variety of articles and have increasingly stringent property requirements. Not only do these adhesives have to have desirable optical properties and maintain these properties in a variety of environmental conditions, but they also have to fulfill the role of an adhesive namely, to adhere together to substituents.

The requirements for optical articles are becoming more demanding. For example, many articles, such as display devices, include a circular polarizer to control the reflection from the surface of the article. In a conventional OLED, since a circular polarizer located in front of the OLED panel is generally required to prevent reflection of ambient light from a metal electrode, only half of the light extracted from the OLED panel reaches the eye. Thus, the use of circular polarizers can decrease the brightness of the article, especially in display devices. Additionally, as devices have become foldable, the need for flexible multi-layer optical articles. Circular polarizers generally are rigid multi-layer polymeric films with a thickness of 50 micrometers or more, and tend to not have suitable flexibility for use in articles where flexibility is needed. Therefore, a need remains for optical articles that are flexible and have low surface reflectivity without using circular polarizers.

Disclosed herein are adhesive compositions that are optically clear and include a narrow band color absorbing dye. The adhesive layers have a desirable combination of adhesive and optical features. The adhesives not only adhere adjacent layers together, but also have a high transmission of visible light and can be used in optical articles that do not contain circular polarizers to decrease the surface reflectivity without substantially decreasing the visible light transmission of the optical article.

The term “adhesive” as used herein refers to polymeric compositions useful to adhere together two adherends. Examples of adhesives are pressure sensitive adhesives.

Pressure sensitive adhesive compositions are well known to those of ordinary skill in the art to possess properties including the following: (1) aggressive and permanent tack, (2) adherence with no more than finger pressure, (3) sufficient ability to hold onto an adherend, and (4) sufficient cohesive strength to be cleanly removable from the adherend. Materials that have been found to function well as pressure sensitive adhesives are polymers designed and formulated to exhibit the requisite viscoelastic properties resulting in a desired balance of tack, peel adhesion, and shear holding power. Obtaining the proper balance of properties is not a simple process.

The term “(meth)acrylate” refers to monomeric acrylic or methacrylic esters of alcohols. Acrylate and methacrylate monomers or oligomers are referred to collectively herein as “(meth)acrylates”. Materials referred to as “(meth)acrylate functional” are materials that contain one or more (meth)acrylate groups.

The terms “room temperature” and “ambient temperature” are used interchangeably to mean temperatures in the range of 20° C. to 25° C.

The terms “polymer” and “macromolecule” are used herein consistent with their common usage in chemistry. Polymers and macromolecules are composed of many repeated subunits. As used herein, the term “macromolecule” is used to describe a group attached to a monomer that has multiple repeating units. The term “polymer” is used to describe the resultant material formed from a polymerization reaction.

The term “alkyl” refers to a monovalent group that is a radical of an alkane, which is a saturated hydrocarbon. The alkyl can be linear, branched, cyclic, or combinations thereof and typically has 1 to 20 carbon atoms. In some embodiments, the alkyl group contains 1 to 18, 1 to 12, 1 to 10, 1 to 8, 1 to 6, or 1 to 4 carbon atoms. Examples of alkyl groups include, but are not limited to, methyl, ethyl, n-propyl, isopropyl, n-butyl, isobutyl, tert-butyl, n-pentyl, n-hexyl, cyclohexyl, n-heptyl, n-octyl, and ethylhexyl.

Unless otherwise indicated, the terms “optically transparent”, and “visible light transmissive” are used interchangeably, and refer to an article, film or adhesive that has a high light transmittance over at least a portion of the visible light spectrum (about 400 to about 700 nm). Typically, optically transparent articles have a visible light transmittance of at least 90% and a haze of less than 10%.

Unless otherwise indicated, “optically clear” refers to an adhesive or article that has a high light transmittance over at least a portion of the visible light spectrum (about 400 to about 700 nm), and that exhibits low haze, typically less than about 5%, or even less than about 2%. In some embodiments, optically clear articles exhibit a haze of less than 1% at a thickness of 50 micrometers or even 0.5% at a thickness of 50 micrometers. Typically, optically clear articles have a visible light transmittance of at least 95%, often higher such as 97%, 98% or even 99% or higher.

Disclosed herein are adhesive compositions. The adhesive compositions comprise an optically clear pressure sensitive adhesive and at least one light absorbing component dispersed within the pressure sensitive adhesive. The at least one light absorbing component comprises a dye that has a peak absorption at 555-600 nanometers and has a Full Width at Half Maximum (FWHM) of no more than 70 nanometers.

The adhesive composition comprises an optically clear pressure sensitive adhesive. The pressure sensitive adhesive comprises at least one polymeric component and may additionally comprise additional components such a tackifying resins, plasticizing resins, and the like as long as the additives do not interfere with the optical properties of the adhesive composition.

The pressure sensitive adhesive comprises a (meth)acrylate pressure sensitive adhesive, a (meth)acrylate-based pressure sensitive adhesive, a polyolefin pressure sensitive adhesive, a polyurethane pressure sensitive adhesive, or a combination thereof. Each of these classes of polymeric pressure sensitive adhesives are well understood in the adhesive arts. Polyolefin pressure sensitive adhesives, also called a poly(l-alkene) pressure sensitive adhesives, are polymers or co-polymers prepared from olefin monomers. The polymers may also include radiation activatable functional groups grafted thereon as described in U.S. Pat. No. 5,209,971 (Babu, et al). Polyurethane pressure sensitive adhesives useful in the disclosure include, for example, those disclosed in U.S. Pat. No. 3,718,712 (Tushaus); U.S. Pat. No. 3,437,622 (Dahl); and U.S. Pat. No. 5,591,820 (Kydonieus et al.).

In some embodiments, the pressure sensitive adhesive comprises a (meth)acrylate pressure sensitive adhesive or a (meth)acrylate-based pressure adhesive comprising: one or more alkyl (meth)acrylate monomers with 2-18 carbon atoms and may contain one or more hydroxyl groups; and at least one reinforcing monomer. Such pressure sensitive adhesives generally have a glass transition temperature of about −20° C. or less. Examples of suitable alkyl (meth)acrylate monomers include for example, isooctyl acrylate, 2-ethyl-hexyl acrylate, n-butyl acrylate, HEA (hydroxyl ethyl acrylate), and HEMA (hydroxyl ethyl methacrylate). Examples or reinforcing monomers include, for example, (meth)acrylic acid, (meth)acrylamide, ethylene vinyl acetate, N-vinyl pyrrolidone and styrene macromers.

The adhesive composition also comprise at least one light absorbing dye. Suitable dyes are those that have a peak absorption in the range of 555-600 nanometers and have a relatively narrow Full Width at Half Maximum (FWHM) of no more than 70 nanometers. In some embodiments, the dye has a peak absorption in the range of 555-580 nanometers and have a relatively narrow Full Width at Half Maximum (FWHM) of no more than 40 nanometers.

Examples of suitable light absorbing dyes include coordination complex dyes. Commercially available dyes include VIS589A and VIS591A from QCR Solution Corp., EPOLIGHT 5699 from Epolin LLC, Newark, NJ; FDG-007 from Yamada Chemical Co. Ltd. Kyoto, Japan: Other useful materials may include those coordination complex dyes with absorption in the range of 480-510 nm, for example DSL500B from Crysta-Lyn, Binghampton, NY. and FDB-007 from Yamada Chemical Co. Ltd. Kyoto, Japan:

The amount of dye present in the adhesive composition can be varied as desired, but generally only a very small amount of dye is necessary to provide the desired results. In some embodiments, the dye comprises 0.05-0.50% by weight of the total weight of the adhesive composition, or even 0.05-0.2% by weight.

The adhesive composition has a variety of desirable properties. The adhesive composition has a peak absorption at 555-600 nanometers and has a Full Width at Half Maximum (FWHM) of no more than 70 nanometers. In some embodiments, the adhesive composition has a peak absorption at 555-580 nanometers and has a Full Width at Half Maximum (FWHM) of no more than 40 nanometers.

The fact that the adhesive composition has the same peak absorption profile as the added dye is indicative that the dye has excellent compatibility with pressure sensitive adhesive and is therefore essentially fully dissolved in the pressure sensitive adhesive matrix. This compatibility aids in preventing the agglomeration of the dye into particles that do not function well as light absorbers and can inhibit the transmission of light.

The adhesive composition is capable of forming a pressure sensitive adhesive layer of 15-200 micrometers, wherein the pressure sensitive adhesive layer has a peak absorption at 555-600 nanometers and has a Full Width at Half Maximum (FWHM) of no more than 70 nanometers.

Also disclosed herein are optical articles. In some embodiments, the article comprises an optical substrate with a first major surface and a second major surface, and an adhesive layer disposed on at least a portion of the first major surface of the optical substrate. The adhesive layer comprises an adhesive composition as described above. Thus, the adhesive layer comprises an adhesive composition comprising an optically clear pressure sensitive adhesive and at least one light absorbing component dispersed within the pressure sensitive adhesive. The at least one light absorbing component comprises a dye that has a peak absorption at 555-600 nanometers and has a Full Width at Half Maximum (FWHM) of no more than 70 nanometers.

A wide range of optical substrates are suitable. In some embodiments, the optical substrate is an optical film substrate. The optical film substrate may be a mono-layer film substrate or a multi-layer film substrate. Typically, the film substrate is optically clear. In some embodiments, the film substrates provide flexible cover layers.

In many embodiments, the optical substrate comprises an optical device. Examples of suitable optical devices include display devices. Examples of suitable display devices include an OLED (Organic Light Emitting Diode). The optical devices often comprise additional layers. Examples of suitable layers include cover layers and touch sensor layers.

In some embodiments, the optical device comprises an OLED and a cover layer, with the adhesive layer therebetween. In other embodiments, the devices are more complicated with multi-layer optical stack disposed on the cover plate of the OLED. The multi-layer stack may be adhered to the multi-layer stack by the adhesive layer of this disclosure. The additional layers of the multi-layer optical stack can include layers such as touch sensor layers, cover layers, and one or more additional adhesive layers.

As mentioned above, one advantage of the adhesive layers of this disclosure is that they can be used in optical multi-layer articles where the multi-layer articles do not include a circular polarizer. Circular polarizers are generally included to reduce the reflection of the optical articles. It has been discovered that the current adhesive layers reduce the reflection of the optical articles by filtering narrow light absorption between green and red emitting light of display devices such as OLED devices.

The articles include adhesive layers that are optically clear pressure sensitive adhesives with at least one light absorbing dye as described above. In some embodiments, the adhesive layer has a peak absorption at 555-600 nanometers and has a Full Width at Half Maximum (FWHM) of no more than 70 nanometers. In other embodiments, the adhesive layer has a peak absorption at 555-580 nanometers and has a Full Width at Half Maximum (FWHM) of no more than 40 nanometers.

In some embodiments, the adhesive layer causes a decrease in surface reflection of the article of up to 80% with a retention of visible light transmission of at least 70% when compared to the article without the layer of adhesive composition. In other embodiments, the adhesive layer causes a decrease in surface reflection of the article of up to 50% with a retention of visible light transmission of at least 80% when compared to the article without the layer of adhesive composition. In these embodiments, reflection is defined as the relative reduction in reflection as compared to an equivalent article without the dye-containing adhesive layer. Visible light transmission is measured by the emission of light through the article and is defined as the relative reduction in light emission as compared to an equivalent article without the dye-containing adhesive layer.

The adhesive layer has a thickness of from 15-200 micrometers. The adhesive layer comprises an optically clear pressure sensitive adhesive and a light absorbing dye. In some embodiments, the dye comprises 0.05-0.50% by weight of the total weight of the adhesive composition, or even 0.05-0.20% by weight.

### EXAMPLES

These examples are merely for illustrative purposes only and are not meant to be limiting on the scope of the appended claims. All parts, percentages, ratios, etc. in the examples and the rest of the specification are by weight, unless noted otherwise. The following abbreviations are used: nm=nanometers: ppm=parts per million; g=grams: mol=moles: IV=inherent viscosity; dL=deciliters; min=minutes. The terms “weight %”, “% wt”, and “wt %” are used interchangeably.

Table of Abbreviations

| Abbreviation | |
|---|---|
| or Trade | |
| Designation | Description |
| 2-EHA | 2-Ethylhexyl acrylate, available from BASF |
| IBOA | Isobornyl acrylate available from SAN ESTERS |
| | CORPORATION |
| 2-HEA | 2-Hydroxyethyl Acrylate available from Yinyan, |
| | China |
| AEBP | 4-acryloyloxyethoxy benzophenone, 50% in ethyl |
| | acetate |
| Initiator-1 | Available as VAZO-67 from AkzoNobel |
| Initiator-2 | Available as IRGACURE 819 (10% solid in MEK) |
| | from Ciba |
| EA | Ethyl acetate available from Eastman |
| MEK | Methyl ethyl ketone |
| Dye-1 | Visible absorbing dye, commercially available as |
| | VIS589A from QCR Solution Crop. Port Saint |
| | Lucie, Florida |
| Dye-2 | Visible absorbing dye, commercially available as |
| | VIS591A from QCR Solution Crop. Port Saint |
| | Lucie, Florida |
| Dye-3 | Visible absorbing dye, commercially available as |
| | EPOLIGHT 5699 from Epolin LLC, Newark, NJ |
| Dye-4 | Visible absorbing dye, commercially available as |
| | DSL500B from Crysta-Lyn, Binghampton, NY |
| Liner-1 | RF12N, a PET based release liner from SKC |
| Liner-2 | RF02N, a PET based release liner from SKC |
| PET | Polyethylene terephthalate |

### Test Methods

### Transmission Spectra of Selected Dye Solutions

The transmission spectra of selected dyes were measured using a Lambda 1050. First, Dye-1, Dye-2, and Dye-3 were dissolved in methyl ethyl ketone to about 100 ppm concentration. Dye-4 was dissolved in methanol to about 100 ppm concentration. For Dye-1, Dye-2, and Dye-3, MEK solvent was used as reference, however, for Dye-4, methanol was used as reference during the T % measurement using Lambda 1050. The diluted dye absorptions were listed in Table 1.

TABLE 1
Transmission spectra of selected dyes in solvent

| | λ Max (nm) | T % at λ Max | FWHM (nm) | % T at 520 nm |
|---|---|---|---|---|
| Dye-1 | 590 | 43.4 | 23 | 98.4 |
| Dye-2 | 592 | 53 | 20 | 99.1 |
| Dye-3 | 592 | 43.9 | 26 | 97.6 |
| Dye-4 | 504 | 40.4 | 52 | 72.2 |

### Sample Preparation

### 1. Adhesive Polymer Preparation

To a reactor was charged 936.6 g 2-EHA, 187.5 g IBOA, 125 g 2-HEA, 1.88 g AEBP (50% in EA), and 1870 g EA. The monomer solution was mixed for 10 minutes, and the reactor temperature was increased to 65° C. At the same time, 1.25 g of Intiator-1 was pre-dissolved in 5 g EA. The Initiator-1 solution was added into the reactor. After that, oxygen in the reactor and solution were removed by purging N₂ at 65° C. multiple times to kick off the polymerization. The reaction was held at 65° C. for 24 hours. The polymer solution was drained from the reactor as a clear and viscous solution at 40% solids content. The IV of the polymer was measured at 0.85 dL/g (Mw is at about 500,000 g/mol).

### 2. Color Filtering OCA Preparation: Examples 1-3

### Preparation of Color Filter OCA Solutions

### Example 1: Color Filter OCA Solution 1

In a 4 ounce brown jar, 0.03 g of Dye-1, 22.5 g of MEK, 30.1 g of base OCA solution prepared above (47.2% wt), and 0.45 g of Initiator-2 were mixed together. The mixture was placed on a roller mixer overnight.

### Examples 2 and 3: Color Filter OCA Solution 2 and 3

The adhesive solutions were made as above, but using Dye-2 (Example 2), and Dye-3 (Example 3) instead of Dye-1.

### Preparation of Adhesive Layers

### Examples 1-3

On a lab coater, the adhesive solutions 1-3, were coated on a Liner-1 using a knife coater, the coating thickness were controlled by the gap between the knife and release liner. The dry coating thickness is controlled at 25 micrometers. Then, the coated films were placed in 70° C. drying oven for 20 min. The samples were removed from the oven, and Liner-2 was laminated on the dried adhesive surfaces. The adhesive samples between Liner-1 and Liner-2 liners were finally cured using a lab benchtop UV-LED light system, operated at 365 nm wavelength with input light intensity of 2 Amps for 1 min.

### Measurement of Optical Properties of Color Filter OCAs

The spectra of the 3 color filter OCAs were measured using Lambda 1050. The results are shown below in Table 2:

TABLE 2
Optical properties of color filter OCAs

| | | λ Max | T % at | FWHM | % T at |
|---|---|---|---|---|---|
| Examples | Dye | (nm) | λ Max | (nm) | 520 nm |
| I | Dye-1 | 590 | 18.9 | 26 | 91.8 |
| 2 | Dye-2 | 594 | 19.1 | 27 | 92.2 |
| 3 | Dye-3 | 592 | 13.6 | 28 | 90.2 |

A comparison of the spectra of dyes in OCA matrix (Table 2) and solvent (Table 1), the dye absorption peak is slightly red shifted, but the full width at half maximum (FWHM) is also only slight broadened, suggesting that the dye is well-dispersed in OCA matrix without aggregations.

### Modeling Studies

### Effect of Absorption Spectral Properties on Emission and Reflection

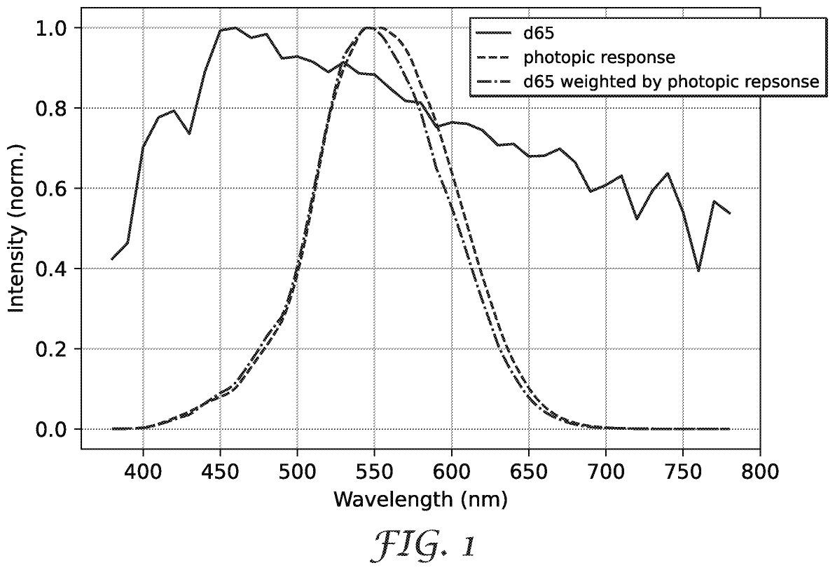

To examine the performance space achievable with this concept, we implemented an optical model to predict the impact of the dye design on the emission and reflection of an OLED display. For the reduction of ambient light, we tabulated the reduction in reflection of the CIE standard illuminant D65 spectrum weighted by the photopic sensitivity of the human eye. These spectra can be seen in FIG. 1:

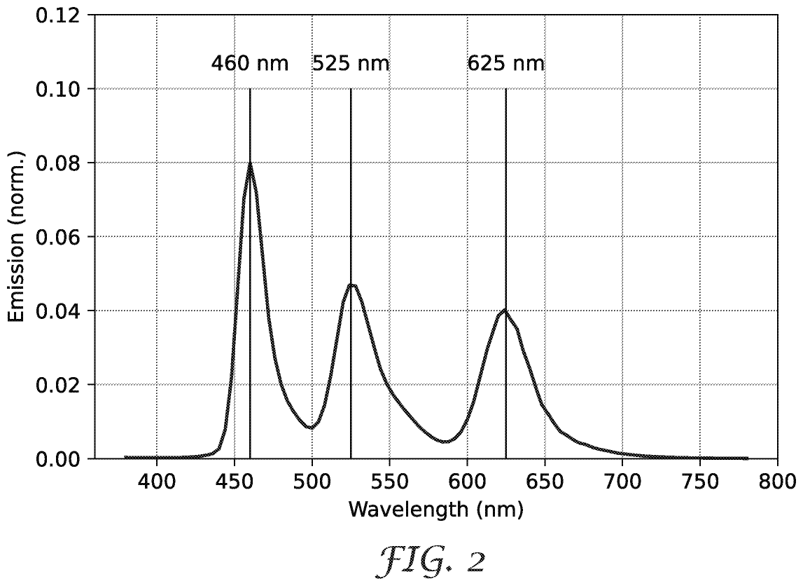

For the potential reduction of an OLED display, we tabulated the reduction of an example OLED white spectrum consisting of blue, green, and red emission bands as showing in FIG. 2:

First an understanding of the performance space for an archetypical dye was developed having an absorption spectrum defined by a Gaussian distribution. The dye absorption peak was then parametrized by its peak location, peak full-width at half-maximum (FWHM), and its peak absorbance when measured as a stand-alone film. Absorbance (A) is defined via the following equation where I₀ an initial intensity of a light source, I is the final intensity of a light source after traversing the film, and λ is the wavelength of the light source.

I[λ]=I₀[λ]10^{-A[λ]}

Reflection is defined as the relative reflection as compared to an equivalent display without color-filter material. Emission is defined as the relative emission as compared to an equivalent display without color-filter material. In general, the goal is to minimize the reflection while maximizing the emission.

In a first examination, we varied the peak location of the dye absorption between the green and red emission peaks of the white OLED spectrum. Table 3 summarizes the results of the optical model where the absorbance was systematically varied to target specific levels of device reflection (25%, 50%, 75%, and 90%). For a target device reflection of 25% we observe an optimal dye peak wavelength of 565 nm. For a target device reflection of 50% we observe an optimal dye peak wavelength of 575 nm. For a target device reflection of 75% we observe an optimal dye peak wavelength of 575 nm. For a target device reflection of 90% we observe an optimal dye peak wavelength of 575 nm.

TABLE 3

| Reflection | Dye Peak | Dye Peak | Film | Emission |
|---|---|---|---|---|
| (%) | Wavelength (nm) | FWHM (nm) | Absorbance | (%) |
| 25 | 535 | 50 | 4.343 | 62.9 |
| 25 | 545 | 50 | 3.083 | 65.9 |
| 25 | 555 | 50 | 2.693 | 68.1 |
| 25 | 565 | 50 | 3.127 | 68.2 |
| 25 | 575 | 50 | 4.343 | 65.5 |
| 50 | 525 | 50 | 0.738 | 75.4 |
| 50 | 535 | 50 | 0.565 | 79.2 |
| 50 | 545 | 50 | 0.521 | 82.4 |
| 50 | 555 | 50 | 0.478 | 85.3 |
| 50 | 565 | 50 | 0.521 | 87.2 |
| 50 | 575 | 50 | 0.651 | 87.3 |
| 50 | 585 | 50 | 0.869 | 84.2 |
| 50 | 595 | 50 | 1.433 | 77.0 |
| 50 | 605 | 50 | 3.387 | 69.2 |
| 75 | 525 | 50 | 0.217 | 90.0 |
| 75 | 535 | 50 | 0.174 | 91.3 |
| 75 | 545 | 50 | 0.174 | 92.7 |
| 75 | 555 | 50 | 0.174 | 94.0 |
| 75 | 565 | 50 | 0.174 | 95.0 |
| 75 | 575 | 50 | 0.174 | 95.3 |
| 75 | 585 | 50 | 0.217 | 94.6 |
| 75 | 595 | 50 | 0.261 | 92.3 |
| 75 | 605 | 50 | 0.391 | 88.3 |
| 75 | 615 | 50 | 0.565 | 82.4 |
| 75 | 625 | 50 | 1.086 | 75.4 |
| 90 | 525 | 50 | 0.043 | 96.3 |
| 90 | 535 | 50 | 0.043 | 96.8 |
| 90 | 545 | 50 | 0.043 | 97.3 |
| 90 | 555 | 50 | 0.043 | 97.8 |
| 90 | 565 | 50 | 0.043 | 98.2 |
| 90 | 575 | 50 | 0.043 | 98.3 |
| 90 | 585 | 50 | 0.087 | 98.1 |
| 90 | 595 | 50 | 0.087 | 97.3 |
| 90 | 605 | 50 | 0.087 | 96.0 |
| 90 | 615 | 50 | 0.130 | 94.0 |
| 90 | 625 | 50 | 0.217 | 91.4 |

In a second examination, we varied the peak FWHM of the dye absorption spectrum when the dye peak location was 575 nm. Again, Table 4 summarizes the results of the optical model when the film absorbance is varied to target several levels of reflection reduction. For a target device reflection of 25% we observe an optimal dye peak FWHM of 80 nm. For a target device reflection of 50% we observe an optimal dye peak FWHM of 30 nm. For a target device reflection of 75% we observe an optimal dye peak FWHM of 30 nm. For a target device reflection of 90% we observe an optimal dye peak FWHM less than 30 nm.

TABLE 4

| Reflection | Dye Peak | Dye Peak | Film | Emission |
|---|---|---|---|---|
| (%) | Wavelength (nm) | FWHM (nm) | Absorbance | (%) |
| 25 | 575 | 50 | 4.343 | 65.5 |
| 25 | 575 | 60 | 1.954 | 66.0 |
| 25 | 575 | 70 | 1.129 | 67.3 |
| 25 | 575 | 80 | 0.825 | 67.5 |
| 25 | 575 | 90 | 0.695 | 67.1 |
| 25 | 575 | 100 | 0.608 | 66.3 |
| 50 | 575 | 30 | 4.343 | 88.0 |
| 50 | 575 | 40 | 1.173 | 87.9 |
| 50 | 575 | 50 | 0.651 | 87.3 |
| 50 | 575 | 60 | 0.434 | 86.1 |
| 50 | 575 | 70 | 0.347 | 85.0 |
| 50 | 575 | 80 | 0.304 | 83.9 |
| 50 | 575 | 90 | 0.261 | 83.0 |
| 50 | 575 | 100 | 0.261 | 82.1 |
| 75 | 575 | 20 | 0.955 | 96.6 |
| 75 | 575 | 30 | 0.391 | 96.7 |
| 75 | 575 | 40 | 0.261 | 96.1 |
| 75 | 575 | 50 | 0.174 | 95.3 |
| 75 | 575 | 60 | 0.174 | 94.5 |
| 75 | 575 | 70 | 0.130 | 93.8 |
| 75 | 575 | 80 | 0.130 | 93.2 |
| 75 | 575 | 100 | 0.087 | 92.2 |
| 90 | 575 | 10 | 0.521 | 99.0 |
| 90 | 575 | 20 | 0.174 | 99.0 |
| 90 | 575 | 30 | 0.087 | 98.9 |
| 90 | 575 | 40 | 0.087 | 98.6 |
| 90 | 575 | 50 | 0.043 | 98.3 |
| 90 | 575 | 60 | 0.043 | 98.0 |
| 90 | 575 | 70 | 0.043 | 97.7 |
| 90 | 575 | 80 | 0.043 | 97.5 |
| 90 | 575 | 90 | 0.043 | 97.3 |
| 90 | 575 | 100 | 0.043 | 97.1 |

In a third examination, we co-optimized the peak location, peak FWHM, and Absorbance of the dye film to target several different reflection reductions. The results are summarized in Table 5:

TABLE 5

| Reflection | Dye Peak | Dye Peak | Film | Emission |
|---|---|---|---|---|
| (%) | Wavelength (nm) | FWHM (nm) | Absorbance | (%) |
| 10.2 | 552 | 68 | 4.343 | 50.5 |
| 18.9 | 557 | 74 | 1.119 | 64.1 |
| 30.3 | 563 | 62 | 0.877 | 75.0 |
| 43.8 | 570 | 44 | 1.117 | 84.7 |
| 52.3 | 572 | 37 | 1.108 | 89.4 |
| 60.7 | 574 | 32 | 0.927 | 92.9 |
| 70.4 | 576 | 27 | 0.698 | 95.7 |
| 82.1 | 579 | 20 | 0.473 | 98.1 |

The combined results from these three investigations allow us to determine a general set of parameters that can be used to identify and select optimal dyes according to their absorption spectrum. It should be noted that the optimal set of values will depend on both the specific emission spectrum of the OLED, the spectrum of ambient light, and the sensitivity of the viewing.

What is claimed is:

1. An adhesive composition comprising:
an optically clear pressure sensitive adhesive; and
at least one light absorbing component dispersed within the pressure sensitive adhesive, wherein the at least one light absorbing component comprises a dye that has a peak absorption at 555-600 nanometers and has a Full Width at Half Maximum (FWHM) of no more than 70 nanometers.

2. The adhesive composition of claim 1, wherein the adhesive composition has a peak absorption at 555-600 nanometers and has a Full Width at Half Maximum (FWHM) of no more than 70 nanometers.

3. The adhesive composition of claim 1, wherein the adhesive composition has a peak absorption at 555-580 nanometers and has a Full Width at Half Maximum (FWHM) of no more than 40 nanometers.

4. The adhesive composition of claim 1, wherein the pressure sensitive adhesive comprises a (meth)acrylate pressure sensitive adhesive, a (meth)acrylate-based pressure sensitive adhesive, a polyolefin pressure sensitive adhesive, a polyurethane pressure sensitive adhesive, or a combination thereof.

5. The adhesive composition of claim 1, wherein the pressure sensitive adhesive comprises a (meth)acrylate pressure sensitive adhesive or a (meth)acrylate-based pressure adhesive comprising:
one or more alkyl (meth)acrylate monomers with 2-18 carbon atoms, and may contain
one or more hydroxyl groups; and
at least one reinforcing monomer.

6. The adhesive composition of claim 1, wherein the light absorbing dye comprises a coordination complex.

7. The adhesive composition of claim 1, wherein the dye comprises 0.05-0.50% by weight of the total weight of the adhesive composition.

8. The adhesive composition of claim 1, wherein the adhesive composition is capable of forming pressure sensitive adhesive layer of 15-200 micrometers, wherein the pressure sensitive adhesive layer has a peak absorption at 555-600 nanometers and has a Full Width at Half Maximum (FWHM) of no more than 70 nanometers.

9. An article comprising:
an optical substrate with a first major surface and a second major surface, and an adhesive layer disposed on at least a portion of the first major surface of the optical substrate, wherein the adhesive layer comprises an adhesive composition comprising:
an optically clear pressure sensitive adhesive; and
at least one light absorbing component dispersed within the pressure sensitive
adhesive, wherein the at least one light absorbing component comprises a dye that has
a peak absorption at 555-600 nanometers and has a Full Width at Half Maximum (FWHM) of no more than 70 nanometers.

10. The article of claim 9, wherein the adhesive layer has a peak absorption at 555-600 nanometers and has a Full Width at Half Maximum (FWHM) of no more than 70 nanometers.

11. The article of claim 9, wherein the adhesive layer has a peak absorption at 555-580 nanometers and has a Full Width at Half Maximum (FWHM) of no more than 40 nanometers.

12. The article of claim 9, wherein the optical substrate comprises an optical device.

13. The article of claim 12, wherein the optical device comprises an OLED (Organic Light Emitting Diode).

14. The article of claim 13, wherein the article further comprises a cover layer.

15. The article of claim 9, wherein the article comprises a multi-layer article, wherein the optical substrate comprises an OLED (Organic Light Emitting Diode) panel; and further comprising a cover layer; and
a touch sensor.

16. The article of claim 15, wherein the multi-layer article does not include a circular polarizer.

17. The article of claim 9, wherein the adhesive layer causes a decrease in surface reflection of the article of up to 80% with a retention of visible light transmission of at least 70% when compared to the article without the layer of adhesive composition.

18. The article of claim 9, wherein the adhesive layer causes a decrease in surface reflection of the article of up to 50% with a retention of visible light transmission of at least 80% when compared to the article without the layer of adhesive composition.

19. The article of claim 9, wherein the adhesive layer has a thickness of from 15-200 micrometers.

20. The article of claim 9, wherein the dye comprises 0.05-0.50% by weight of the total weight of the adhesive composition.
